(19) United States
(12) Patent Application Publication
(10) Pub. No.: US 2026/0150677 A1
(43) Pub. Date: May 28, 2026

(54) THREE-DIMENSIONAL STACKED CHIP AND METHOD FOR MANUFACTURING THE SAME

(71) Applicant: INNOSILICON TECHNOLOGY INC., Ottawa (CA)

(72) Inventors: Hai AO, Ottawa (CA); Zhuan GAO, Ottawa (CA)

(21) Appl. No.: 19/086,850

(22) Filed: Mar. 21, 2025

(30) Foreign Application Priority Data
Nov. 28, 2024 (CN) 202411721565.9

(51) Int. Cl. H01L 23/373; H01L 21/768; H01L 23/00; H01L 23/48; H01L 25/00; H01L 25/16; H10B 80/00

(52) U.S. Cl. CPC H10W 40/255; H10W 20/023; H10W 72/90; H10W 90/00; H10B 80/00; H10W 20/20

(57) ABSTRACT

The present disclosure relates to a three-dimensional stacked chip and a method for manufacturing the same. The three-dimensional stacked chip includes a substrate, a first storage module, and a logic module. The first storage module and the logic module are sequentially stacked on the substrate, and the first storage module is arranged between the logic module and the substrate. The first storage module is configured to provide and store data required by the logic module, and support the logic module to complete corresponding work. The logic module is configured to exchange signals with the outside through the first storage module, and achieve one or more of the following objectives through a side opposite to the first storage module: connecting to a power supply, connecting to the ground, and exchanging signals with the outside. The disclosure can avoid impact of heat generated by the logic module on the storage module.

### TECHNICAL FIELD

The present invention relates to the field of integrated circuit technologies, and more specifically, to a three-dimensional stacked chip and a method for manufacturing the same.

### BACKGROUND

With the outburst of large language models in AI applications, artificial intelligence software has raised higher requirements on the chip design industry. A conventional chip architecture and supporting storage far cannot meet requirements of large language models for large bandwidths and high capacities. To meet the needs of explosive AI development, researches and development of novel chip architectures and new storage technologies need to be accelerated.

### SUMMARY

In view of the foregoing defects or improvement requirements of the related art, the present invention provides a three-dimensional stacked chip and a method for manufacturing the same, to avoid impact of heat generated by a logic module on a storage module, and significantly improve power consumption tolerance for the logic module. In addition, an additional layer is added to provide support with sufficient strength throughout an entire process and form a conductive connection between the logic module and a heat dissipation module.

To achieve the foregoing objective, according to one aspect of the present disclosure, the three-dimensional stacked chip includes a substrate, a first storage module, and a logic module, where the first storage module and the logic module are sequentially stacked on the substrate, and the first storage module is arranged between the logic module and the substrate; the first storage module is configured to provide and store data required by the logic module, and support the logic module to complete corresponding work; and the logic module is configured to perform signal exchange with the outside through the first storage module and the substrate, and achieve one or more of the following objectives through a side opposite to the first storage module: connecting to a power supply, connecting to the ground, and exchanging signals with the outside.

In some implementations, the three-dimensional stacked chip further includes one or more stacked second storage modules, where the one or more stacked second storage modules are arranged between the first storage module and the logic module to form a storage module stacked structure with the first storage module; and the one or more stacked second storage modules are configured to provide and store data required by the logic module, and support the logic module to complete corresponding work; and the logic module is configured to perform signal exchange with the outside through the storage module stacked structure and the substrate, and achieve one or more of the following objectives through a side opposite to the storage module stacked structure: connecting to a power supply, connecting to the ground, and exchanging signals with the outside.

In some implementations, the logic module is configured to perform signal exchange with the outside through the side opposite to the storage module stacked structure.

In some implementations, the logic module is connected to a power supply by the storage module stacked structure, and is connected to the ground by the side opposite to the storage module stacked structure.

In some implementations, the logic module is connected to the ground by the storage module stacked structure, and is connected to a power supply by the side opposite to the storage module stacked structure.

In some implementations, the logic module is connected to a power supply and the ground by the side opposite to the storage module stacked structure.

In some implementations, the three-dimensional stacked chip further includes a heat dissipation module arranged on the logic module.

In some implementations, the three-dimensional stacked chip further includes an additional layer, configured to provide support in a manufacturing process of the three-dimensional stacked chip.

In some implementations, the three-dimensional stacked chip further includes an additional layer arranged between the logic module and the heat dissipation module, where the logic module forms a conductive connection to the heat dissipation module through the additional layer.

In some implementations, the additional layer is connected to the heat dissipation module through a conductive spacer layer; one or more conductive connection paths are formed in the conductive spacer layer; and the logic module is configured to achieve one or more of the following objectives through the one or more conductive connection paths and the heat dissipation module: connecting to a power supply, connecting to the ground, and exchanging signals with the outside.

In some implementations, the additional layer is capable of performing a logic function.

In some implementations, the additional layer is arranged between the first storage module and the substrate, and the first storage module is conductively connected to the substrate through the additional layer.

According to another aspect of the present disclosure, a method for manufacturing a three-dimensional stacked chip is provided, including:
forming a first stacked structure, where the first stacked structure includes a logic structure, and one or more second storage modules and a first storage structure sequentially stacked on the logic structure;
forming a second stacked structure by using an additional structure and the first stacked structure, where:
   the second stacked structure includes an additional layer, a first storage module, and the one or more second storage modules and a logic module sequentially stacked on the first storage module; and
   the first storage module is obtained by processing the first storage structure, the logic module is obtained by processing the logic structure, and the additional layer is obtained by processing the additional structure; and
connecting a surface of the second stacked structure opposite to the logic module to the substrate.

In some implementations, the forming a second stacked structure by using an additional structure and the first stacked structure includes:
obtaining the logic module by processing the logic structure;
combining the additional structure and the logic module;
obtaining the first storage module by processing the first storage structure; and
obtaining the additional layer by processing the additional structure.

In some implementations, the logic structure includes a second substrate, and a logic device and a second interconnect layer formed on the second substrate; and
the obtaining the logic module by processing the logic structure includes:
   thinning the second substrate of the logic structure;
   forming through-silicon vias (TSVs) running through the thinned second substrate; and
   forming another second interconnect layer on the thinned second substrate.

In some implementations, the first storage structure includes a first substrate, and a first storage device and a first interconnect layer formed on the first substrate; and
the obtaining the first storage module by processing the first storage structure includes:
   thinning the first substrate of the first storage structure; and
   forming TSVs running through the thinned first substrate.

In some implementations, the additional structure includes a fourth substrate and a fifth interconnect layer formed on the fourth substrate; and
the obtaining the additional layer by processing the additional structure includes forming TSVs running through the fourth substrate of the additional structure.

In some implementations, the second storage module includes a thinned third substrate, a second storage device and a third interconnect layer formed on the third substrate, and a fourth interconnect layer formed on a back of the thinned third substrate.

In some implementations, the method for manufacturing a three-dimensional stacked chip further includes arranging a heat dissipation module on the additional layer.

In some implementations, the method for manufacturing a three-dimensional stacked chip further includes forming a conductive spacer layer and a heat dissipation module sequentially on the additional layer, where the additional layer is connected to the heat dissipation module through the conductive spacer layer, and a conductive connection path or a plurality of conductive connection paths insulated from each other are formed in the conductive spacer layer.

In general, compared with the related art, the foregoing technical solutions conceived in the present disclosure has the following beneficial effects: The storage module stacked structure is arranged between the logic module and the substrate, so that the logic module is arranged on the storage module stacked structure, thereby providing great convenience for heat dissipation of the logic module. The logic module is closer to the heat dissipation module than the storage module stacked structure, which avoids impact of heat generated by the logic module on the storage modules, and significantly improves power consumption tolerance for the logic module. In addition, an additional layer is added between the logic module and the heat dissipation module or between the storage module and the substrate to provide support with sufficient strength throughout the entire process, ensure that the logic module may have a reasonable through-silicon via size by fully thinning, and form a conductive connection between the logic module and the heat dissipation module.

### BRIEF DESCRIPTION OF THE DRAWINGS

FIG. 1 is a schematic structural diagram of a three-dimensional stacked chip;

FIG. 2 is a schematic structural diagram of a three-dimensional stacked chip according to an embodiment of the present invention;

FIG. 3A is a schematic structural diagram of a three-dimensional stacked chip according to another embodiment of the present invention;

FIG. 3B is a schematic structural diagram of a three-dimensional stacked chip according to another embodiment of the present invention;

FIG. 4 is a schematic structural diagram of a three-dimensional stacked chip according to another embodiment of the present invention;

FIG. 5A to FIG. 5L are schematic diagrams of a method for manufacturing a three-dimensional stacked chip according to an embodiment of the present invention; and

FIG. 6 is a schematic flowchart of manufacturing a three-dimensional stacked chip according to an embodiment of the present invention.

### DETAILED DESCRIPTION

To make the objectives, technical solutions, and advantages of the present invention clearer and more understandable, the present invention is further described below in detail with reference to accompanying drawings and embodiments. It should be understood that the specific embodiments described herein are used only for describing the present invention, and are not intended to limit the present invention. As a person skilled in the art can realize, the described embodiments may be modified in various different ways without departing from the spirit or the scope of this application. Therefore, the drawings and the description are to be considered as illustrative in nature but not restrictive.

Stacking a storage module and a logic module in a plurality of layers can multiply a bandwidth and a capacity of a system, so that requirements of a large language model can be fully met. FIG. 1 shows a solution of a three-dimensional stacked chip.

As shown in FIG. 1, a logic module 103 and a plurality of storage modules 105 are sequentially stacked on a substrate 101. The storage modules 105 are arranged on the logic module 103, and the logic module 103 is arranged between the storage modules 105 and the substrate 101, which facilitates providing a proper power supply and the ground for the logic module 103, and facilitates data transfer between the logic module 103 and the outside. In addition, the logic module 103 generates a large amount of heat when running, and the heat is mainly dissipated upward through a side on which the storage modules 105 are located. However, the storage modules 105 are very sensitive to heat, and the storage modules 105 stacked in a plurality of layers further limit heat dissipation. Particularly, when the logic module 103 works with high power consumption, such a stacking manner produces a serious heat accumulation effect, which greatly reduces power consumption tolerance for the logic module 103. Therefore, the three-dimensional stacked chip shown in FIG. 1 cannot meet requirements of a large language model on power consumption and computing power of a logic module.

To improve power consumption tolerance for the logic module and reduce adverse impact of heat accumulation on the storage modules, it is necessary to further improve the three-dimensional stacked chip shown in FIG. 1.

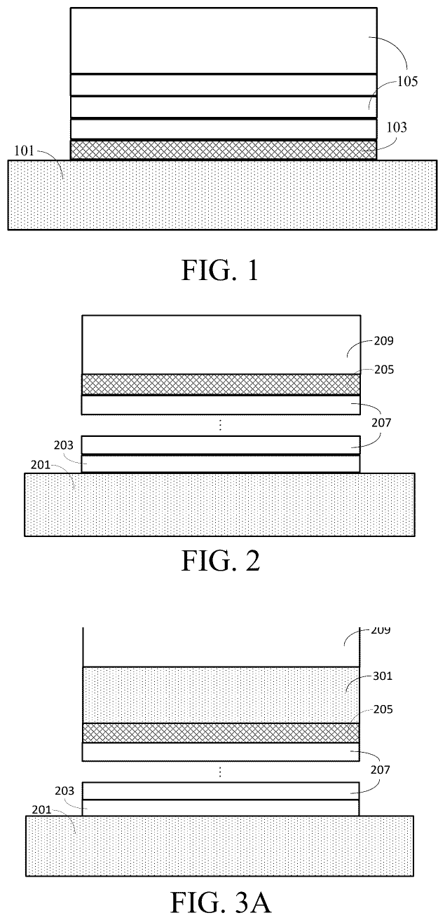

As shown in FIG. 2, a three-dimensional stacked chip in this embodiment of the present invention includes a substrate 201, a first storage module 203, one or more second storage modules 207, and a logic module 205. The first storage module 203, the one or more second storage modules 207, and the logic module 205 are sequentially stacked on the substrate 201. The first storage module 203 and the one or more second storage modules 207 form a storage module stacked structure. The logic module 205 is arranged on the storage module stacked structure. The storage module stacked structure is arranged between the substrate 201 and the logic module 205.

One surface of the first storage module 203 forms a conductive connection to an adjacent second storage module 207, and an other surface of the first storage module 203 forms a conductive connection to the substrate 201. One surface of the logic module 205 forms a conductive connection to an adjacent second storage module 207. When a second storage module 207 is adjacent to another second storage module 207 on one side, the surface of the second storage module 207 on the side forms a conductive connection to the adjacent second storage module 207. When a second storage module 207 is adjacent to another second storage module 207 on both sides, the surfaces of the second storage module 207 on both sides form conductive connections to the corresponding adjacent second storage modules 207.

Further, the logic module 205 forms conductive connections to the first storage module 203 and the one or more second storage modules 207, to enable the logic module 205 to perform data exchange with the first storage module 203 and the one or more second storage modules 207. Specifically, the first storage module 203 and the one or more second storage modules 207 are mainly configured to provide and store data required by the logic module 205, and support the logic module 205 to complete corresponding work. In some implementations, one or more of the first storage module 203 and the one or more second storage modules 207 can further achieve a few logical control functions. To be specific, one or more of the storage modules are a combination of a storage medium and a logical medium. Such a combination may be a one-dimensional structure, or may be a two-dimensional structure or a three-dimensional structure. In some implementations, the function that can be implemented by the logic module 205 includes one or more of computing, control, interfacing, and data processing.

The logic module 205 forms conductive connections to the first storage module 203 and the one or more second storage modules 207, to form conductive paths in the storage module stacked structure, so that the logic module 205 can perform signal exchange with the outside through the storage module stacked structure. In some implementations, the logic module exchanges signals with the outside not only through the storage module stacked structure, but also through a side opposite to the storage module stacked structure. That is to say, the logic module interacts with the outside through an upper path and a lower path for signal exchange. In some implementations, one of the upper path and the lower path is primary and the other is secondary.

In some implementations, the logic module 205 is connected to a power supply by the storage module stacked structure, and is connected to the ground by a side opposite to the storage module stacked structure. In some implementations, the logic module 205 is connected to the ground by the storage module stacked structure, and is connected to a power supply by a side opposite to the storage module stacked structure. In some implementations, the logic module 205 is connected to a power supply and the ground by a side opposite to the storage module stacked structure. In some implementations, the logic module 205 is connected to a power supply and the ground by the storage module stacked structure.

In some implementations, the logic module 205 includes a plurality of stacked sub-logic modules, and adjacent surfaces of the plurality of stacked sub-logic modules form a conductive connection. In some implementations, the first storage module 203 and the one or more second storage module 207 are mainly configured to provide and store data required by the plurality of stacked sub-logic modules, and support the plurality of stacked sub-logic modules to complete corresponding work. In some implementations, a sub-logic module closer to the storage module stacked structure has lower power, and a sub-logic module farther away from the storage module stacked structure has higher power, which helps dissipate heat of the sub-logic module with higher power, and reduces impact of heat on the storage module.

In some implementations, the one or more second storage modules 207 may be omitted, to replace the storage module stacked structure with the first storage module 203. To be specific, one surface of the first storage module 203 forms a conductive connection to the logic module 205, and an other surface of the first storage module 203 forms a conductive connection to the substrate 201. The foregoing solution of arranging the logic module on the storage module is still applicable to a case in which there is only one storage module.

In some implementations, the foregoing manner of forming a conductive connection includes one or more of hybrid bonding and a conductive bump connection. Generally, a side on which a device is formed is a front side (face), and the other side is a back side (back). In some implementations, the logic module forms a conductive connection to a storage module in a face-to-face manner, and one storage module forms a conductive connection to another storage module in a face-to-back manner. In other implementations, the logic module forms a conductive connection to a storage module in a back-to-face manner, which means that a back of the logic module is connected to a face of the storage module, and one storage module forms a conductive connection to another storage module in a face-to-back manner. It should be understood that a connection may be formed in other possible manners between the logic module and a storage module, and between two storage modules.

In some implementations, the first storage module 203 may be directly or indirectly arranged on the substrate 201, the one or more second storage modules 207 as a whole may also be directly or indirectly arranged on the first storage module 203, and the logic module 205 may also be directly or indirectly arranged on the one or more second storage modules 207. In some implementations, being adjacent refers to being closest, and may be being directly adjacent or indirectly adjacent. For example, when there is no other second storage module 207 or no other structure between two adjacent second storage modules 207, the two adjacent second storage modules 207 are directly adjacent. When there is no other second storage module 207 between two adjacent second storage modules 207, while another structure is further arranged between the two adjacent second storage modules 207, the two adjacent second storage modules 207 are indirectly adjacent. A second storage module 207 adjacent to the first storage module 203 refers to a second storage module 207 closest to the first storage module 203. A second storage module 207 adjacent to the logic module 205 refers to a second storage module 207 closest to the logic module 205.

In some implementations, an external circuit (for example, a GPU/CPU) is further arranged on the substrate 201. The external circuit forms a conductive connection to the first storage module 203 by external interfaces and the substrate 201, and the substrate 201 is connected to a circuit board (not shown in the figure) by external pins. In some implementations, the logic module 205 is connected to the power supply and the ground by the storage module stacked structure and the substrate 201. Further, the logic module 205 obtains a work instruction from the outside (the external circuit) through the substrate 201 and the storage module stacked structure, completes corresponding work, and transmits a processing result (to the external circuit) through the storage module stacked structure and the substrate 201.

In some implementations, a silicon interposer (Si interposer) is arranged between the first storage module 203 and the substrate 201. The Si interposer is used to provide a high-density electrical connection. An external circuit (for example, a GPU/CPU) is further arranged on the Si interposer. The external circuit forms a conductive connection to the first storage module 203 by external interfaces and the Si interposer. The Si interposer further forms a conductive connection to external pins by external interfaces and the substrate 201, and is finally connected to a circuit board (not shown in the figure) by the external pins. In some implementations, the logic module 205 is connected to the power supply and the ground by the storage module stacked structure and the Si interposer. Further, the logic module 205 obtains a work instruction from the outside (the external circuit) through the Si interposer (or the Si interposer and the substrate 201) and the storage module stacked structure, completes corresponding work, and transmits a processing result (to the external circuit) through the storage module stacked structure and the Si interposer (or the Si interposer and the substrate 201).

In some implementations, the substrate 201 is made of one or more of silicon, silicon germanium, germanium, silicon-on-insulator (SOI), and organic matter. In some implementations, the first storage module 203 is a Flash, an RRAM, a DRAM, an MRAM, or an SRAM, and the second storage module 207 is a Flash, an RRAM, a DRAM, an MRAM, or an SRAM.

The structure shown in FIG. 2 provides convenience for the logic module 205 to dissipate heat through the opposite side of the storage module stacked structure by placing the logic module 205 on top of the storage module stacked structure, avoiding heat accumulation caused by the obstruction of heat conduction in both directions of the logic module when the logic module is between the storage module stacked structure and the substrate, and significantly reducing the impact of heat generated by the logic module on the storage module.

Further, a heat dissipation module 209 is arranged on the logic module 205. The heat dissipation module 209 can ensure that a large amount of heat generated by the logic module 205 during high-power-consumption running is dissipated in time, so that power consumption tolerance for the logic module can be significantly increased. In some implementations, the heat dissipation module 209 may be directly or indirectly arranged on the logic module 205. In general, a positional relationship among the storage module stacked structure, the logic module 205, and the heat dissipation module 209 only needs to satisfy that the logic module 205 with high power is closer to the heat dissipation module 209 at the top than the storage module stacked structure.

In some implementations, one or more conductive connection paths are formed between the logic module 205 and the heat dissipation module 209. The logic module 205 utilizes the heat dissipation module 209 to achieve one or more of the following objectives through the one or more conductive connection paths: connecting to a power supply, connecting to the ground, and exchanging signals with the outside. Correspondingly, in some implementations, through-silicon vias (TSVs) running through a substrate of the logic module 205 are formed. On the one hand, TSVs formed in the logic module will occupy a large area if the substrate of the logic module is not thinned, resulting in failure of realizing functional devices in the logic module. Therefore, it is necessary to thin the substrate of the logic module to reduce the size of the TSVs to a reasonable range, so as to realize functional devices in the logic module. On the other hand, to enable the logic module 205 to exchange data with the first storage module 203 and the one or more second storage module 207, and to exchange signals with the outside through the storage module stacked structure, in some implementations, TSVs running through a substrate of the first storage module 203 are formed, and TSVs running through respective substrate of the one or more second storage modules 207 are formed, so that substrates of the first storage module 203 and the one or more second storage module 207 need to be thinned, which may lead to structural damage during a manufacturing process due to insufficient support strength.

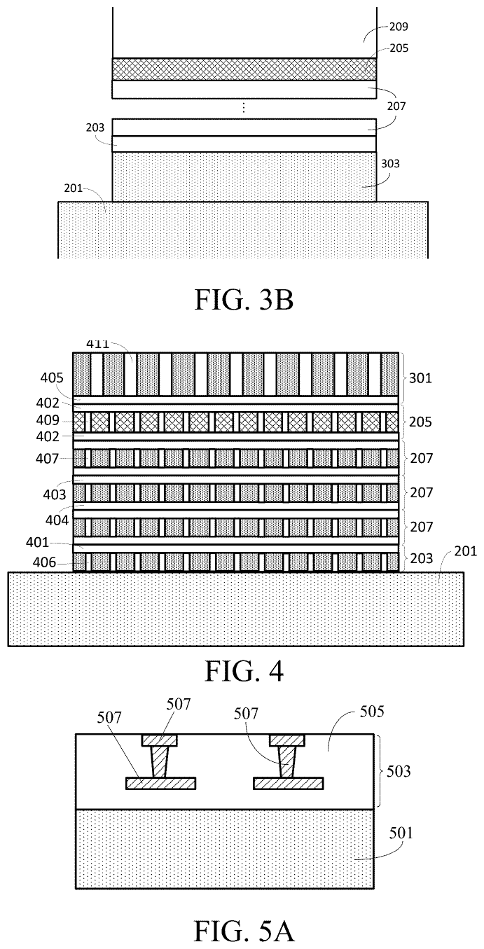

Therefore, in some implementations, as shown in FIG. 3A, an additional layer 301 is added on the logic module 205, and the additional layer 301 is between the logic module 205 and the heat dissipation module 209. In other implementations, as shown in FIG. 3B, an additional layer 303 is added below the first storage module 203, and the additional layer 303 is between the first storage module 203 and the substrate 201.

The additional layer can provide support with sufficient strength throughout an entire process and ensure the logic module 205 to be fully thinned to obtain a reasonable TSV size. As shown in FIG. 3A, the additional layer 301 is used as a transition connection layer to form a conductive connection between the logic module 205 and the heat dissipation module 209. As shown in FIG. 3B, the additional layer 303 is used as a transition connection layer to form a conductive connection between the first storage module 203 and the substrate 201. In some implementations, the additional layer is made of a wafer and TSVs are formed in the additional layer. Used as a structure to enhance the support strength, the additional layer maintains a large thickness without being thinned, so that TSVs in the additional layer have a large size which is allowed for the additional layer mainly carries a function of transition connection. Moreover, in the structure shown in FIG. 3A, the additional layer 301 with large-sized TSVs is very friendly to heat dissipation of the logic module. In some implementations, the additional layers in FIG. 3A and FIG. 3B are designed in terms of actual needs and an occupation status of the additional layer by the TSVs. For example, in addition to a function of conductive connection, the additional layer may have a few logic functions.

Further, take arranging an additional layer on a logic module as an example, as shown in FIG. 4, the three-dimensional stacked chip includes three second storage modules 207. The first storage module 203 includes a first substrate and a first interconnect layer 401 arranged on a side of the first substrate. The logic module 205 includes a second substrate and two second interconnect layers 402 arranged on two sides of the second substrate respectively. Each second storage module 207 includes a third substrate and a third interconnect layer 403 and a fourth interconnect layer 404 arranged on two sides of the third substrate. The additional layer 301 includes a fourth substrate and a fifth interconnect layer 405 arranged on a side of the fourth substrate. The first interconnect layer 401 of the first storage module 203 is bonded to a fourth interconnect layer 404 of an adjacent second storage module 207, a second interconnect layer 402 of the logic module 205 is bonded to a third interconnect layer 403 of an adjacent second storage module 207, and another second interconnect layer 402 of the logic module 205 is bonded to the fifth interconnect layer 405 of the additional layer 301.

When a second storage module 207 is adjacent to another second storage module 207 on one side, a third interconnect layer 403 of the second storage module 207 is bonded to a fourth interconnect layer 404 of the adjacent another second storage module 207, or a fourth interconnect layer 401 of the second storage module 207 is bonded to a third interconnect layer 403 of the adjacent another second storage module 207. When a second storage module 207 is adjacent to another second storage module 207 on both sides, a third interconnect layer 403 of the second storage module 207 is bonded to a fourth interconnect layer 404 of the adjacent another second storage module 207 on one side, and a fourth interconnect layer 404 of the second storage module 207 is bonded to a third interconnect layer 403 of the adjacent another second storage module 207 on the other side.

In some implementations, when the one or more second storage modules 207 are removed, and there is only the first storage module 203, the first interconnect layer 401 of the first storage module 203 is bonded to the second interconnect layer 402 of the logic module 205.

In some implementations, the first interconnect layer 401 includes an insulation layer and conductive structures formed in the insulation layer. The second interconnect layer 402 includes an insulation layer and conductive structures formed in the insulation layer. The third interconnect layer 403 includes an insulation layer and conductive structures formed in the insulation layer. The fourth interconnect layer 404 includes an insulation layer and conductive structures formed in the insulation layer. The fifth interconnect layer 405 includes an insulation layer and conductive structures formed in the insulation layer. In some implementations, bonding refers to chemical bonding of insulation layers of two interconnect layers, as well as physical interdiffusion of conductive structures of the two interconnect layers at an interface of the two interconnect layers, thereby forming a bonding interface between the interconnect layers.

The storage module stacked structure further includes a plurality of through silicon vias (TSVs). Specifically, the first storage module 203 includes a plurality of first TSVs 406 running through the first substrate, each second storage module 207 includes a plurality of second TSVs 407 running through the third substrate, the logic module 205 includes a plurality of third TSVs 409 running through the second substrate, and the additional layer 301 includes a plurality of fourth TSVs 411 running through the fourth substrate. In some implementations, forming the first TSVs includes forming hole structures running through the first substrate, and filling the hole structures with insulation material and conductive material. Forming the second TSVs includes forming hole structures running through the third substrate, and filling the hole structures with insulation material and conductive material. Forming the third TSVs includes forming hole structures running through the second substrate, and filling the hole structures with insulation material and conductive material. Forming the fourth TSVs includes forming hole structures running through the fourth substrate, and filling the hole structures with insulation material and conductive material.

Through conductive structures in the first to fourth interconnect layers and the first and second TSVs, the logic module 205 forms conductive connections to the first storage module 203 and the one or more second storage modules 207, and conductive paths are formed in the storage module stacked structure, which enables the logic module 205 to exchange data with the first storage module 203 and the one or more second storage modules 207, and exchange signals with the outside by the storage module stacked structure. In some implementations, the logic module 205 forms one or more conductive connection paths to the heat dissipation module through the third TSVs 409, the second interconnect layer 402, the fifth interconnect layer 405 and the fourth TSVs 411. The logic module 205 utilizes the heat dissipation module to achieve one or more of the following objectives through the one or more conductive connection paths: connecting to a power supply, connecting to the ground, and exchanging signals with the outside.

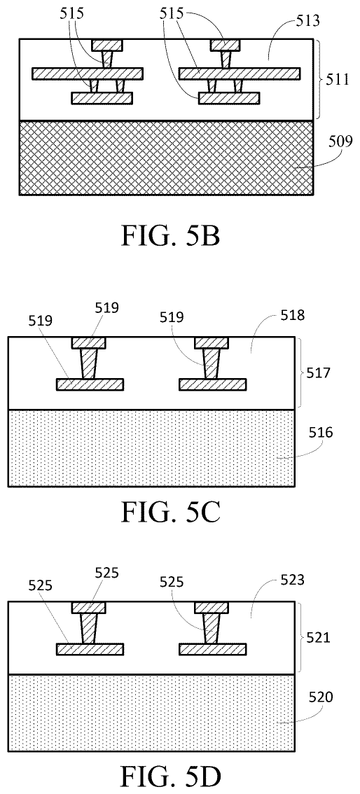

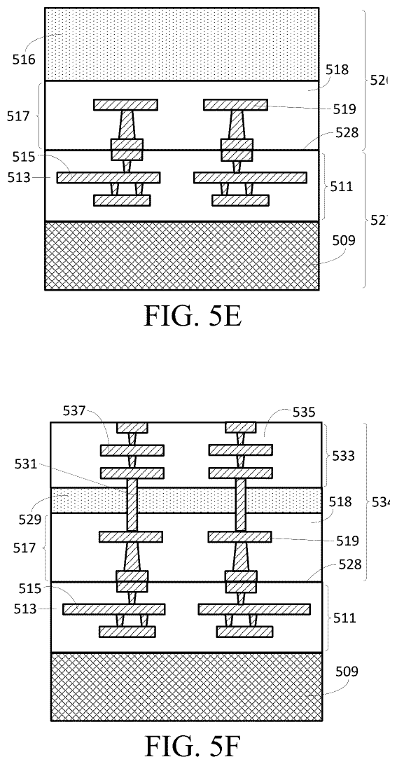

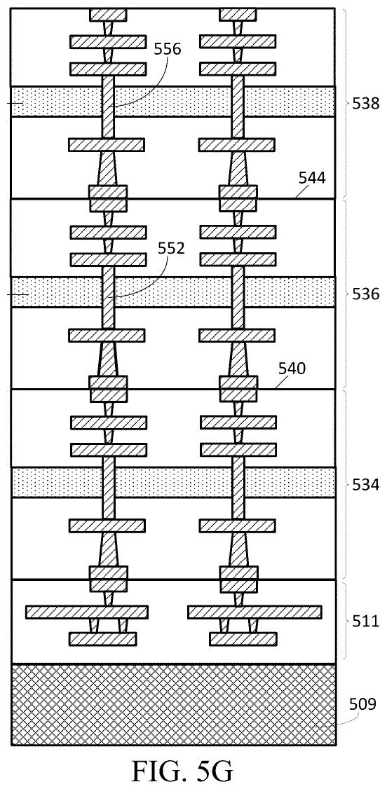

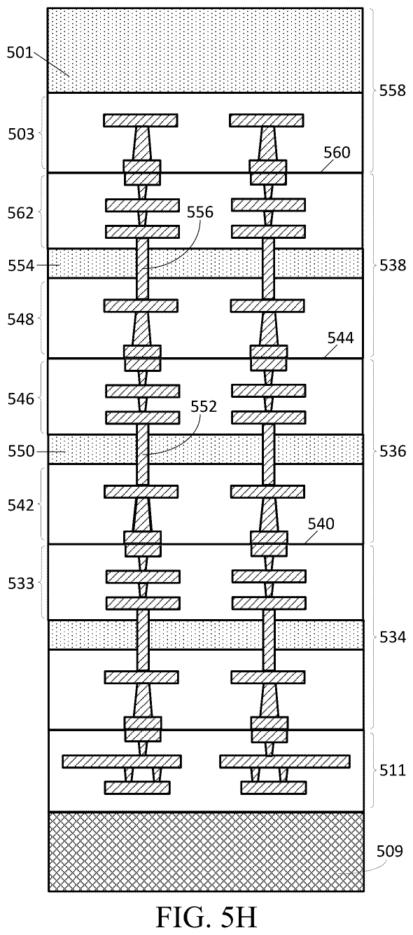

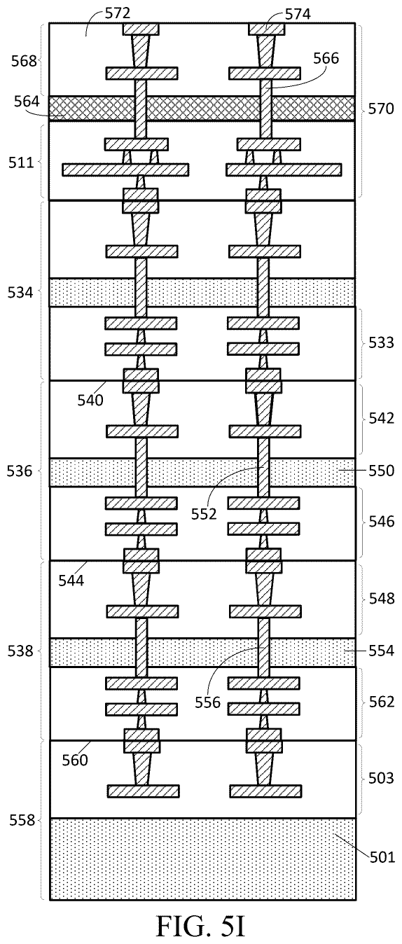

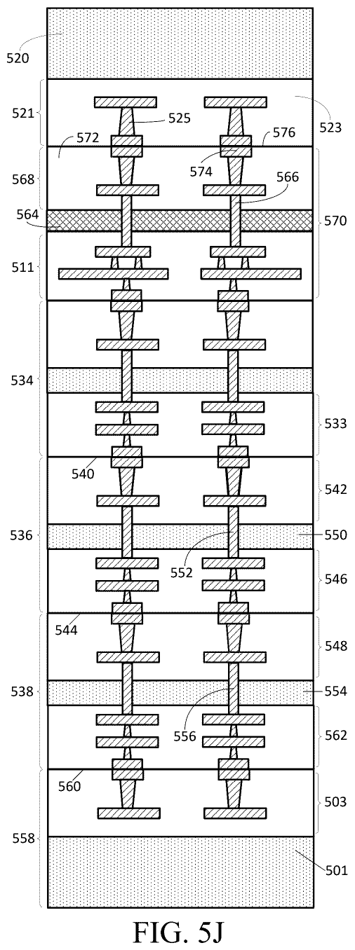

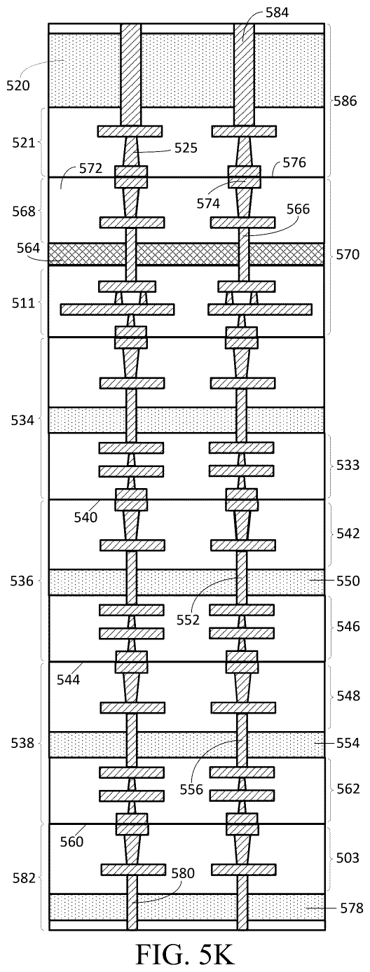

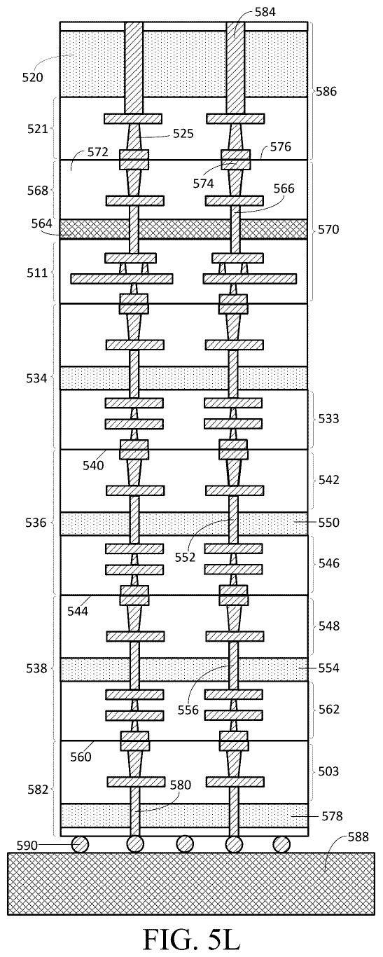

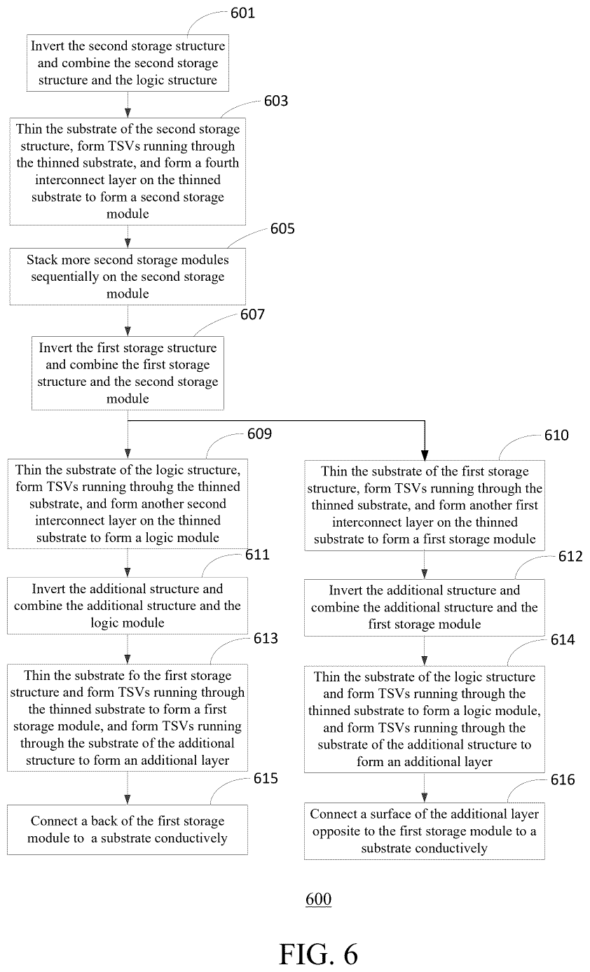

FIG. 5A to FIG. 5L are schematic diagrams of a method for manufacturing a three-dimensional stacked chip according to an embodiment of the present invention. FIG. 6 is a flowchart of an example method 600 for manufacturing a three-dimensional stacked chip. First, with reference to FIG. 5A to FIG. 5D, a process of forming a first storage structure, a logic structure, a second storage structure and an additional structure required for manufacturing a three-dimensional stacked chip is described.

A first storage structure is formed, including: forming a first storage device and a first interconnect layer on a first substrate. As shown in FIG. 5A, a first storage device is formed on a first substrate 501, and then, a first interconnect layer 503 is formed on the first storage device. The first interconnect layer 503 includes an insulation layer 505 and a plurality of conductive structures 507 formed in the insulation layer 505. Apparently, a side on which the first interconnect layer 503 is located is a face of the first storage structure, and a side opposite to the first interconnect layer 503 is a back of the first storage structure. In some implementations, in addition to storage function, the first storage device can also achieve a few logical control functions.

A logic structure is formed, including: forming a logic device and a second interconnect layer on a second substrate. As shown in FIG. 5B, a logic device is formed on a second substrate 509, and then, a second interconnect layer 511 is formed on the logic device. The second interconnect layer 511 includes an insulation layer 513 and a plurality of conductive structures 515 formed in the insulation layer 513. Apparently, a side on which the second interconnect layer 511 is located is a face of the logic module, and a side opposite to the second interconnect layer 511 is a back of the logic module. In some implementations, the function that can be implemented by the logic device includes one or more of computing, control, interfacing, and data processing.

One or more (for example, three) second storage structures are formed in a manner similar to that of the first storage structure. Specifically, a second storage device and a third interconnect layer are formed on a third substrate, to form a second storage structure. As shown in FIG. 5C, a second storage device is formed on a third substrate 516, and then, a third interconnect layer 517 is formed on the second storage device. The third interconnect layer 517 includes an insulation layer 518 and a plurality of conductive structures 519 formed in the insulation layer 518. Apparently, a side on which the third interconnect layer 517 is located is a face of the second storage structure, and a side opposite to the third interconnect layer 517 is a back of the second storage structure. In some implementations, in addition to storage function, one or more of the second storage device can also achieve a few logical control functions.

An additional structure is formed, including: forming a fifth interconnect layer on a fourth substrate. As shown in FIG. 5D, a fifth interconnect layer 521 is formed on a fourth substrate 520. The fifth interconnect layer 521 includes an insulation layer 523 and a plurality of conductive structures 525 formed in the insulation layer 523. In some implementations, forming an additional structure includes: forming a logic device on a fourth substrate and forming a fifth interconnect layer on the logic device. In this case, a side on which the fifth interconnect layer is located is a face of the additional structure, and a side opposite to the fifth interconnect layer is a back of the additional structure. That is to say, in addition to a function of conductive connection, the additional layer may have a few logic functions according to actual needs.

The example method 600 begins with operation 601. As shown in FIG. 6, the second storage structure is inverted, the third interconnect layer is aligned with the second interconnect layer, and the second storage structure and the logic structure are combined, to enable the second storage structure and the logic structure to form a conductive connection through the third interconnect layer and the second interconnect layer. As shown in FIG. 5E, the second storage structure 526 and the logic structure 527 are combined in a face-to-face manner, to form a bonding interface 528. Specifically, forming the bonding interface 528 includes: enabling the insulation layer 518 in the third interconnect layer 517 and the insulation layer 513 in the second interconnect layer 511 to form chemical bonding at an interface, and enabling the conductive structures 519 in the third interconnect layer 517 and the conductive structures 515 in the second interconnect layer 511 to perform physical diffusion at the interface.

The example method 600 continues with operation 603. As shown in FIG. 6, the third substrate of the second storage structure is thinned, TSVs running through the thinned third substrate are formed, and a fourth interconnect layer is formed on the thinned third substrate to form a second storage module. As shown in FIG. 5F, the third substrate 516 of the second storage structure 526 is thinned to obtain a thinned substrate 529, TSVs 531 running through the substrate 529 are formed, and a fourth interconnect layer 533 is further formed on the substrate 529, to form a second storage module 534. The fourth interconnect layer 533 includes an insulation layer 535 and a plurality of conductive structures 537 formed in the insulation layer 535. Apparently, a side on which the fourth interconnect layer 533 is located is a back of the second storage module 534.

The example method 600 continues with operation 605. As shown in FIG. 6, more second storage modules are sequentially stacked on the second storage module in a manner similar to operation 601 and operation 603. As shown in FIG. 5G, a second storage module 536 and a second storage module 538 are sequentially stacked on the second storage module 534. The second storage module 536 and the second storage module 534 are combined in a face-to-back manner to form a bonding interface 540. Specifically, a third interconnect layer 542 of the second storage module 536 is bonded to the fourth interconnect layer 533 of the second storage module 534. The second storage module 538 and the second storage module 536 are combined in a face-to-back manner to form a bonding interface 544. Specifically, a third interconnect layer 548 of the second storage module 538 is bonded to a fourth interconnect layer 546 of the second storage module 536. Similar to the second storage module 534, TSVs 552 running through a substrate 550 are formed in the second storage module 536, and TSVs 556 running through a substrate 554 are formed in the second storage module 538.

The example method 600 continues with operation 607. As shown in FIG. 6, the first storage structure is inverted, the first interconnect layer is aligned with the fourth interconnect layer, and the first storage structure and the second storage module are combined, to enable the first storage structure and the second storage module to form a conductive connection through the first interconnect layer and the fourth interconnect layer and obtain a first stacked structure including the logic structure, the plurality of second storage module and the first storage structure. As shown in FIG. 5H, the first storage structure 558 and the second storage module 538 are combined in a face-to-back manner to form a bonding interface 560. Specifically, the first interconnect layer 503 of the first storage structure 558 is bonded to a fourth interconnect layer 562 of the second storage module 538.

The example method 600 continues with operation 609. As shown in FIG. 6, the first stacked structure is inverted, the second substrate of the logic structure is thinned, TSVs running through the thinned second substrate are formed, and another second interconnect layer is formed on the thinned second substrate to form a logic module. As shown in FIG. 5I, the first stacked structure is inverted, the second substrate 509 of the logic structure is thinned to obtain a thinned substrate 564, TSVs 566 running through the substrate 564 are formed, and another second interconnect layer 568 is formed on the substrate 564 to form a logic module 570. The second interconnect layer 568 includes an insulation layer 572 and a plurality of conductive structures 574 formed in the insulation layer 572. Apparently, a side on which the second interconnect layer 568 is located is a back of the logic module 570.

In some implementations, the example method 600 continues with operation 610. As shown in FIG. 6, the first substrate of the first storage structure is thinned, TSVs running through the thinned first substrate are formed, and another first interconnect layer is formed on the thinned first substrate to form a first storage module.

In some implementations, the insulation layer in the first to fifth interconnect layers is one or more layers of insulation material, for example, silicon oxide, silicon nitride, silicon oxynitride, or a combination thereof. In some implementations, a process of forming conductive structures in the first to fifth interconnect layers includes: first forming openings in the insulation layer, and then filling required openings with conductive material. In some implementations, conductive material for manufacturing the conductive structures includes, but is not limited to, tungsten, cobalt, copper, aluminum, doped silicon, silicide, or a combination of the foregoing materials. In some implementations, the openings may be filled with the conductive material by using ALD, CVD, PVD, and/or another suitable method.

The example method 600 continues with operation 611. As shown in FIG. 6, the additional structure is inverted, the fifth interconnect layer is aligned with the second interconnect layer, and the additional structure and the logic module are combined to enable the additional structure and the logic module to form a conductive connection through the fifth interconnect layer and the second interconnect layer. As shown in FIG. 5J, the additional structure and the logic module are combined in a face-to-back manner to form a bonding interface 576. Specifically, forming the bonding interface 576 includes: enabling the insulation layer 523 in the fifth interconnect layer 521 and the insulation layer 572 in the second interconnect layer 568 to form chemical bonding at an interface, and enabling the conductive structures 525 in the fifth interconnect layer 521 and the conductive structures 574 in the second interconnect layer 568 to perform physical diffusion at the interface.

In some implementations, the example method 600 continues with operation 612. As shown in FIG. 6, the additional structure is inverted, the fifth interconnect layer is aligned with the first interconnect layer, and the additional structure and the first storage module are combined to enable the additional structure and the first storage module to form a conductive connection through the fifth interconnect layer and the first interconnect layer.

The example method 600 continues with operation 613. As shown in FIG. 6, the first substrate of the first storage structure is thinned, and TSVs running through the thinned first substrate are formed to form a first storage module. TSVs running through the fourth substrate of the additional structure are formed to form an additional layer. A second stacked structure including the first storage module and the plurality of second storage modules, the logic module and the additional layer sequentially stacked on the first storage module is obtained. As shown in FIG. 5K, the first substrate 501 of the first storage structure is thinned to obtain a thinned substrate 578, and TSVs 580 running through the substrate 578 are formed to form a first storage module 582. TSVs 584 running through the fourth substrate 520 of the additional structure are formed to form an additional layer 586. That is to say, the additional layer is not thinned, so it can provide excellent support for the second stacked structure and avoid damage when the second stacked structure is connected to the substrate.

In some implementations, the example method continues with operation 614. As shown in FIG. 6, the second substrate of the logic structure is thinned, and TSVs running through the thinned second substrate are formed to form a logic module. TSVs running through the fourth substrate of the additional structure are formed to form an additional layer. A second stacked structure including the additional layer and the first storage module, the plurality of second storage module and the logic module sequentially stacked on the additional layer is obtained.

The example method 600 continues with operation 615. As shown in FIG. 6, a back of the first storage module is conductively connected to a substrate. As shown in FIG. 5L, a back of the first storage module 582 forms a conductive connection to a substrate 588 through conductive bumps 590, and an other surface of the substrate 588 is connected to a circuit board through conductive bumps.

In some implementations, the example method continues with operation 616. As shown in FIG. 6, a surface of the additional layer opposite to the first storage module is conductively connected to a substrate.

In some implementations, the first storage module further includes an interconnect layer formed on its back, and the first storage module forms a conductive connection to the substrate through the interconnection layer.

In some implementations, an external circuit is further arranged on the substrate, and the external circuit forms a conductive connection to the first storage module through conductive structures in the substrate.

In some implementations, a Si interposer is introduced, the back of the first storage module forms a conductive connection to the Si interposer, the Si interposer forms a conductive connection to the substrate through conductive bumps, and further, an other surface of the substrate is connected to a circuit board by conductive bumps. In some implementations, an external circuit is further arranged on the Si interposer, and the external circuit forms a conductive connection to the first storage module through the Si interposer and conductive structures in the substrate.

In some implementations, a heat dissipation module is arranged on the back of the additional layer and the back of the additional layer forms a conductive connection to the heat dissipation module. A great number of large-sized TSVs are formed in the additional layer, which helps to dissipate a large amount of heat generated by the logic module during high-power operation. In some implementations, the additional layer further includes an interconnect layer formed on its back, and the additional layer forms a conductive connection to the heat dissipation module through the interconnect layer. In some implementations, the additional layer is connected to the heat dissipation module through a conductive spacer layer. In some implementations, a conductive connection path or a plurality of conductive connection paths insulated from each other are formed in the conductive spacer layer, and the logic module achieve one or more of the following objectives through the one or more conductive connection paths: connecting to a power supply, connecting to the ground, and exchanging signals with the outside.

In the above method, the step of forming one or more second storage structures can be omitted. Correspondingly, the first storage structure is inverted and combined with the logic module to form a conductive connection through the first interconnect layer and the second interconnect layer.

It should be noted that the foregoing method for manufacturing a three-dimensional stacked chip is merely illustrative, and should not be used to form a limitation on the present invention. Content and/or a sequence of steps in the foregoing method may be adjusted according to actual needs to obtain a same or similar technical effect. For example, the process of forming the first storage structure and the process of forming the logic module are independent of each other and are not in sequence. In addition, the step of combining the second storage structure and the logic module may be performed after the first storage structure is formed, or may be performed before the first storage structure is formed.

In the present disclosure, the storage module stacked structure is arranged between the logic module and the substrate, so that the logic module is arranged on the storage module stacked structure, thereby providing great convenience for heat dissipation of the logic module. The logic module is closer to the heat dissipation module than the storage module stacked structure, which avoids impact of heat generated by the logic module on the storage modules, and significantly improves power consumption tolerance for the logic module. In addition, an additional layer is added between the logic module and the heat dissipation module or between the storage module and the substrate to provide support with sufficient strength throughout the entire process, ensure that the logic module may have a reasonable through-silicon via size by fully thinning, and form a conductive connection between the logic module and the heat dissipation module.

In description of the present disclosure, references to “one embodiment,” “some embodiments,” “an example,” “a specific example,” “some examples,” etc., indicate that a particular feature, structure, material, or characteristic described in the embodiment or example can be included in at least one embodiment or example of the disclosure. Moreover, the particular feature, structure, material, or characteristic described can be combined in any one or more embodiments or examples in a reasonable way. Besides, it would be within the knowledge of a person skilled in the pertinent art to affect such feature, structure, material, or characteristic in connection with other embodiments or examples without contradiction.

Moreover, terms such as “first” and “second” are just for illustration which should not be interpreted as indicating or implying relative importance, or implying number of the indicated feature. Thus, a feature described by “first” or “second” can include at least one of the feature explicitly or implicitly. In description of the present disclosure, “multiple” means two or more, unless otherwise specified.

Any process or method described in a flowchart or otherwise herein can be interpreted as including one or more (two or more than two) modules, fragments or sections of executable code to implement steps of a specified logical function or process. Also, the scope of preferred embodiments of the disclosure includes alternative implementations where the function can be performed out of the order shown or discussed, including performing the function in a substantially simultaneous way or in a reverse order.

The logic and/or steps described in a flowchart or otherwise herein, for example, can be a list of executable code to implement a logic function, which can be embodied in any computer-readable medium and can be used by or in combination with an instruction execution system, apparatus or device (e.g., a computer-based system, a system including a processor, or other systems capable of reading and executing instructions from an instruction execution system, apparatus or device).

It should be understood that various parts of the present disclosure can be implemented by hardware, software, firmware, or a combination thereof. In the foregoing embodiments, various steps or methods can be implemented by software or firmware stored in a memory and executed by a suitable instruction execution system. All or part of the steps of the methods in the foregoing embodiments can be implemented by controlling relevant hardware through a program, which can be stored in a computer-readable storage medium and can implement one or a combination of the steps of the method of the embodiment when executed.

In addition, all the functional units in each embodiment of the disclosure can either be integrated in one processing module, or be separate units, or two or more of the functional units are integrated in one module. The integrated module can be implemented by hardware or by functional modules of software. Being implemented in the form of software functional modules and being sold or used as a separate product, the integrated module mentioned above can also be stored in a computer-readable storage medium, which could be a read-only memory, a magnetic disk, an optical disk, and the like.

The foregoing description covers only embodiments of the disclosure, it should be understood that the scope of the disclosure is not limited thereto. A person skilled in the pertinent art will recognize that various variations and alternatives can be used without departing from the spirit and scope of the present disclosure. Therefore, scope of the present disclosure is subject to scope of the claims.

What is claimed is:

1. A three-dimensional stacked chip, comprising:
a substrate, a first storage module, and a logic module, wherein:
the first storage module and the logic module are sequentially stacked on the substrate, and the first storage module is arranged between the logic module and the substrate;
the first storage module is configured to provide and store data required by the logic module, and support the logic module to complete corresponding work; and
the logic module is configured to perform signal exchange with the outside through the first storage module and the substrate, and achieve one or more of the following objectives through a side opposite to the first storage module: connecting to a power supply, connecting to the ground, and exchanging signals with the outside.

2. The three-dimensional stacked chip of claim 1, further comprising:
one or more stacked second storage modules, wherein:
the one or more stacked second storage modules are arranged between the first storage module and the logic module to form a storage module stacked structure with the first storage module; and
the one or more stacked second storage modules are configured to provide and store data required by the logic module, and support the logic module to complete corresponding work; and
the logic module is configured to perform signal exchange with the outside through the storage module stacked structure and the substrate, and achieve one or more of the following objectives through a side opposite to the storage module stacked structure:
connecting to a power supply, connecting to the ground, and exchanging signals with the outside.

3. The three-dimensional stacked chip of claim 2, wherein:
the logic module is configured to perform signal exchange with the outside through the side opposite to the storage module stacked structure.

4. The three-dimensional stacked chip of claim 2, wherein:
the logic module is connected to a power supply by the storage module stacked structure, and is connected to the ground by the side opposite to the storage module stacked structure.

5. The three-dimensional stacked chip of claim 2, wherein:
the logic module is connected to the ground by the storage module stacked structure, and is connected to a power supply by the side opposite to the storage module stacked structure.

6. The three-dimensional stacked chip of claim 2, wherein:
the logic module is connected to a power supply and the ground by the side opposite to the storage module stacked structure.

7. The three-dimensional stacked chip of claim 2, further comprising a heat dissipation module arranged on the logic module.

8. The three-dimensional stacked chip of claim 7, further comprising an additional layer, configured to provide support in a manufacturing process of the three-dimensional stacked chip.

9. The three-dimensional stacked chip of claim 7, further comprising an additional layer arranged between the logic module and the heat dissipation module, wherein the logic module forms a conductive connection to the heat dissipation module through the additional layer.

10. The three-dimensional stacked chip of claim 9, wherein:
the additional layer is connected to the heat dissipation module through a conductive spacer layer;
one or more conductive connection paths are formed in the conductive spacer layer; and
the logic module is configured to achieve one or more of the following objectives through the one or more conductive connection paths and the heat dissipation module: connecting to a power supply, connecting to the ground, and exchanging signals with the outside.

11. The three-dimensional stacked chip of claim 8, wherein the additional layer is capable of performing a logic function.

12. The three-dimensional stacked chip of claim 8, wherein the additional layer is arranged between the first storage module and the substrate, and the first storage module is conductively connected to the substrate through the additional layer.

13. A method for manufacturing a three-dimensional stacked chip, comprising:
forming a first stacked structure, wherein the first stacked structure comprises a logic structure, and one or more second storage modules and a first storage structure sequentially stacked on the logic structure;
forming a second stacked structure by using an additional structure and the first stacked structure, wherein:
the second stacked structure comprises an additional layer, a first storage module, and the one or more second storage modules and a logic module sequentially stacked on the first storage module; and
the first storage module is obtained by processing the first storage structure, the logic module is obtained by processing the logic structure, and the additional layer is obtained by processing the additional structure; and
connecting a surface of the second stacked structure opposite to the logic module to the substrate.

14. The method for manufacturing a three-dimensional stacked chip of claim 13, wherein the forming a second stacked structure by using an additional structure and the first stacked structure comprises:
obtaining the logic module by processing the logic structure;
combining the additional structure and the logic module;
obtaining the first storage module by processing the first storage structure; and
obtaining the additional layer by processing the additional structure.

15. The method for manufacturing a three-dimensional stacked chip of claim 14, wherein:
the logic structure comprises a second substrate, and a logic device and a second interconnect layer formed on the second substrate; and
the obtaining the logic module by processing the logic structure comprises:
thinning the second substrate of the logic structure;
forming through-silicon vias (TSVs) running through the thinned second substrate; and
forming another second interconnect layer on the thinned second substrate.

16. The method for manufacturing a three-dimensional stacked chip of claim 14, wherein:
the first storage structure comprises a first substrate, and a first storage device and a first interconnect layer formed on the first substrate; and
the obtaining the first storage module by processing the first storage structure comprises:
thinning the first substrate of the first storage structure; and
forming TSVs running through the thinned first substrate.

17. The method for manufacturing a three-dimensional stacked chip of claim 14, wherein:
the additional structure comprises a fourth substrate and a fifth interconnect layer formed on the fourth substrate; and
the obtaining the additional layer by processing the additional structure comprises forming TSVs running through the fourth substrate of the additional structure.

18. The method for manufacturing a three-dimensional stacked chip of claim 13, wherein the second storage module comprises a thinned third substrate, a second storage device and a third interconnect layer formed on the third substrate, and a fourth interconnect layer formed on a back of the thinned third substrate.

19. The method for manufacturing a three-dimensional stacked chip of claim 13, further comprising: arranging a heat dissipation module on the additional layer.

20. The method for manufacturing a three-dimensional stacked chip of claim 13, further comprising: forming a conductive spacer layer and a heat dissipation module sequentially on the additional layer, wherein the additional layer is connected to the heat dissipation module through the conductive spacer layer, and a conductive connection path or a plurality of conductive connection paths insulated from each other are formed in the conductive spacer layer.
